(19) United States
(12) Patent Application Publication
(10) Pub. No.: US 2008/0186059 A1
(43) Pub. Date: Aug. 7, 2008

(54) SEMICONDUCTOR INTEGRATED CIRCUIT

(75) Inventor: Mitsushi NOZOE, Osaka (JP)

Correspondence Address: GREENBLUM & BERNSTEIN, P.L.C., 1950 ROLAND CLARKE PLACE, RESTON, VA, 20191, US

(73) Assignee: MATSUSHITA ELECTRIC INDUSTRIAL CO., LTD., Osaka (JP)

(21) Appl. No.: 12/024,481

(22) Filed: Feb. 1, 2008

(30) Foreign Application Priority Data
Feb. 5, 2007 (JP) 2007-025952

(51) Int. Cl. H03K 19/0948

(52) U.S. Cl. 326/103

(57) ABSTRACT

The object of the present invention is to provide a semiconductor integrated circuit which enables reduction in clock skew between cell blocks, while having plural cell blocks in which standard cells with different cell heights are arranged. The semiconductor integrated circuit of the present invention includes a first standard cell and a second standard cell having a cell height different from a cell height of the first standard cell, and in a P-well region of the first standard cell, the following are arranged: a pair of N-type diffusion regions; and a P-type diffusion region for supplying first substrate power to the first standard cell, and in a P-well region of the second standard cell, the following are arranged: a pair of N-type diffusion regions; and a P-type diffusion region for supplying second substrate power to the second standard cell. In the semiconductor integrated circuit, a distance between the N-type diffusion regions and the P-type diffusion region of the first standard cell is substantially the same as a distance between the N-type diffusion regions and the P-type diffusion region of the second standard cell.

### BACKGROUND OF THE INVENTION

(1) Field of the Invention

The present invention relates to standard cell-type semiconductor integrated circuits having standard cells with different heights.

(2) Description of the Related Art

Standard cell-type semiconductor integrated circuits are designed in such a manner that the heights of all cells (cell heights) are equal as illustrated in FIG. 1, in order to arrange, in high density, a large number of standard cells without leaving any space. FIG. 1 is a plan view of a cell block 1101, illustrating an example of its layout. The cell block 1101 includes standard cells 1102 in plural columns (four columns in FIG. 1). Here, the cell height of each standard cell 1102 is the outside dimension of the standard cell 1102 in a direction (the Y-axis direction in FIG. 1) perpendicular to the direction in which the standard cells 1102 are arranged, that is, the column direction (the X-axis in FIG. 1), and is illustrated with the notation H in FIG. 1.

In the case where high integration of standard cells is desired, it is efficient to design the semiconductor integrated circuits using standard cells having short cell heights. However, in the case where a large-sized transistor is needed for the semiconductor integrated circuits to operate at a high speed, many small-sized transistors need to be arranged and the large-sized transistor needs to be arranged in parallel with the small-sized transistors, as illustrated in FIG. 2, in order to fit in cell heights.

FIG. 2 is a plan view of one of the standard cells 1102, illustrating an example thereof. In a P-well region 1201, plural N-type diffusion regions 1206 which serve as sources and drains of an N-channel transistor are arranged, and a P-type diffusion region 1202 for substrate power supply is also arranged. In a similar manner, in an N-well region 1203, plural P-type diffusion regions 1207 which serve as sources and drains of a P-channel transistor are arranged, and an N-type diffusion region 1204 for substrate power supply is also arranged. In the N-channel transistor, the N-type diffusion regions 1206 which serve as sources are connected to each other via a wire so as to serve as source electrodes. In the P-channel transistor, the P-type diffusion regions 1207 which serve as sources are connected to each other via a wire so as to serve as source electrodes. Further, gate electrodes 1205 are also connected to each other.

As illustrated in FIG. 2, in the case where plural transistors are arranged and connected to each other in parallel in order to structure a large-sized transistor, the standard cell 1102 becomes wide, causing a problem that many wires are needed for connecting the sources, the gates and the drains of the transistors, which results in area inefficiency. In addition, having plural smaller-sized transistors instead of having a single larger-sized transistor causes deterioration in the characteristics of the standard cells, even when smaller-sized transistors have the same size. For example, the length of time for propagating a signal becomes longer.

Therefore, in the case of structuring a large-sized transistor, it is efficient, in terms of areas, to make the cell heights taller, as illustrated in FIG. 3. FIG. 3 is a plan view of one of the standard cells 1102, illustrating an example thereof. Note that the parts in FIG. 3 that correspond to the parts in FIG. 2 are denoted by the same numerical references, and the descriptions thereof are omitted.

However, in the case where the standard cells having different heights are arranged in the same column of the same cell block, the different heights of the standard cells create dead space, causing area inefficiency.

For the reasons described above, only the standard cells with the same cell heights are arranged in one column. Thus, conventionally, standard cells with tall cell heights which are necessary in order for large-sized transistors to operate at high speeds are arranged in a cell block, separately from a cell block in which standard cells with short cell heights for the purpose of area efficiency are arranged.

Incidentally, for semiconductor integrated circuits having plural cell blocks, a clock signal is supplied in a tree-like fashion using standard cells for supplying clocks, in order to supply clock signals to a flip-flop of each cell block. This is because it is necessary to match the points of time that a clock signal reaches flip-flops. The time lag of the clock signal in reaching the flip-flops is called clock skew. The method described above of supplying a clock signal in a tree-like fashion is called Clock Tree Synthesis (CTS). In the case where clock signals are supplied by CTS to plural cell blocks having different cell heights, transistors arranged in the standard cells having different cell heights differ in size, and thus the characteristics of the transistors also differ from each other, causing a problem that the clock skew increases. FIG. 4 is a circuit diagram, schematically illustrating this. In FIG. 4, clock signals are supplied to flip-flops 1303 in a cell block 1301 and to flip-flops 1304 in a cell block 1302. The clock signals are supplied via clock cells (standard cells for supplying clocks) 1305 in the cell block 1301, and via clock cells 1306 in the cell block 1302. Note that in FIG. 4, the size of the transistors in the clock cells 1305 is indicated by the size of the symbols of three buffer circuits corresponding to the clock cells 1305, and the size of the transistors in the clock cells 1306 is indicated by the size of the symbols of three buffer circuits corresponding to the clock cells 1306. The clock cells 1305 include buffer circuits having transistors that differ in size and characteristics from transistors of buffer circuits included in the clock cells 1306. Therefore, the length of delay of output signals outputted from the clock cells 1305 in response to the clock signal differs from that of the clock cells 1306, causing a problem that clock skew between the cell block 1301 and the cell block 1302 increases.

In order to solve the above described problem, the conventional technique has matched the lengths of delays by making following sizes and shapes the same between standard cells with different cell heights used for clocks: the sizes of the transistors, that is, the gate widths and the areas of source and drain diffusion regions; and the shapes of transistors (For example, refer to FIG. 2 of Japanese Unexamined Patent Application Publication No. 2004-79702, hereinafter referred to as Patent Reference 1).

FIGS. 5A and 5B are plan views of standard cells for supplying clocks in an example of the conventional technique disclosed in the above mentioned Patent Reference 1. As the figures illustrate, the standard cells with different cell heights have the same gate widths, areas of source and drain diffusion regions, and shapes of the transistors. Note that FIG. 5A illustrates a standard cell for supplying clocks having a short cell height, whereas FIG. 5B illustrates a standard cell for supplying clocks having a tall cell height. Note also that the parts in FIGS. 5A and 5B which correspond to the parts in FIG. 2 are denoted by the same numerical references and the descriptions thereof are omitted.

### SUMMARY OF THE INVENTION

Incidentally, the technology of processing semiconductor devices is now in the deep sub-micron era, and wire widths have increasingly been miniaturized. Therefore, even minute changes to the shape of polysilicon wires, for example, caused by optical proximity effect can no longer be disregarded. The optical proximity effect is a phenomenon in which the shape of polysilicon wires change in accordance with the distance between a polysilicon wire and another polysilicon wire in proximity. In other words, the optical proximity effect is a phenomenon in which the degree of precision of wire patterns degrades at the time of exposure, which occurs when wire patterns of a semiconductor device are more miniaturized and highly densified. A change in the shape of polysilicon wires in turn has an impact on the gate widths of transistors. As a result, delay characteristics of the transistors are affected.

In a similar manner, in diffusion regions, delay characteristics of the transistors are affected in accordance the distance between boundaries of diffusion regions adjacent to each other or between boundaries of well regions adjacent to each other.

Here, in the example of the conventional technique disclosed in the above mentioned Patent Reference 1, the distances, in the standard cell having the short cell height (FIG. 5A), between the source and drain diffusion regions of the transistor and the diffusion regions for substrate power supply differ from that in the standard cell having the tall cell height (FIG. 5B). Further, as illustrated in FIGS. 6A and 6B, in the case where plural standard cells 1402 are arranged in cell blocks 1401, a distance (a), in a cell block including the standard cells with a short cell height (FIG. 6A), between a gate electrode 1403 in a standard cell 1402 and another gate electrode 1403 in another standard cell 1402 in a different column differs from a distance (a) in a cell block including the standard cells with a tall cell height (FIG. 6B).

As a result, in the example of the conventional technique disclosed in the above mentioned Patent Reference 1, there is a problem that there are differences in the distances between the diffusion regions in standard cells and in the distances between the gates in the standard cells in different columns in accordance with the cell heights of the standard cells, causing a difference in the delay characteristics of the transistors, which results in an increase in clock skew.

Therefore, the present invention has been conceived in view of the above described circumstances, and an object thereof is to provide a semiconductor integrated circuit which enables reduction in clock skew between cell blocks, while having plural cell blocks in which standard cells with different cell heights are arranged.

In order to achieve the above described object, the semiconductor integrated circuit of the present invention includes: a first standard cell in which a first well of a first conductivity type is formed; and a second standard cell in which a second well of the first conductivity type is formed, a cell height of the second standard cell being different from a cell height of the first standard cell. In the first well of the above described semiconductor integrated circuit, the following are arranged: a first diffusion region included in a first transistor; and a second diffusion region for supplying first substrate power to the first standard cell, and in the second well of the above described semiconductor integrated circuit, the following are arranged: a third diffusion region included in a second transistor; and a fourth diffusion region for supplying second substrate power to the second standard cell, and a distance between the first diffusion region and the second diffusion region is substantially the same as a distance between the third diffusion region and the fourth diffusion region.

Here, the first standard cell may include a first metal wire in a first metal wire layer, the first metal wire being connected with the first transistor, the second standard cell may include a second metal wire in the first metal wire layer, the second metal wire being connected with the second transistor, and the first metal wire and the second metal wire may have substantially the same shapes.

In addition, the cell height of the second standard cell may be taller than the cell height of the first standard cell, the first standard cell may include a gate electrode included in the first transistor, the second standard cell may include a dummy gate wire and a gate electrode included in the second transistor, and a distance between the gate electrode of the second standard cell and the dummy gate wire may be twice as long as a distance between the gate electrode of the first standard cell and a boundary between the first standard cell and a cell adjacent to the first standard cell.

With this structure, it is possible to substantially match, between the first and second transistors, the characteristics and the lengths of time for propagating a signal. As a result, it is possible to reduce clock skew between cell blocks in the semiconductor integrated circuit having plural cell blocks in which standard cells with different cell heights are arranged.

According to the present invention, it is possible to provide a semiconductor integrated circuit which enables matching of the characteristics between standard cells and reduction in clock skew between cell blocks, while having plural cell blocks in which standard cells with different cell heights are arranged.

Further Information about Technical Background To this Application

The disclosure of Japanese Patent Application No. 2007-025952 filed on Feb. 5, 2007 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings which illustrate a specific embodiment of the invention. In the Drawings:

FIG. 1 is a plan view of a conventional cell block, illustrating an example of its layout;

FIG. 2 is a plan view of a conventional standard cell, illustrating an example of its layout;

FIG. 3 is a plan view of a conventional standard cell having a tall cell height, illustrating an example of its layout;

FIG. 4 is a schematic diagram of a Clock Tree Synthesis (CTS);

FIG. 5A is a layout diagram of a conventional standard cell having a short cell height;

FIG. 5B is a layout diagram of a conventional standard cell having a tall cell height;

FIG. 6A is a layout diagram of a cell block having standard cells with a short cell height;

FIG. 6B is a layout diagram of a cell block having standard cells with a tall cell height;

FIG. 7 is a plan view of a semiconductor integrated circuit according to a first embodiment of the present invention, illustrating a layout thereof;

FIG. 8A is a layout diagram of a standard cell for supplying clocks, provided within a cell block illustrated in FIG. 7;

FIG. 8B is a layout diagram of a standard cell for supplying clocks, provided within a cell block illustrated in FIG. 7;

FIG. 9 is a diagram illustrating a transistor-level circuit of a standard cell for supplying clocks;

FIG. 10 is a circuit configuration diagram illustrating a route that a clock signal propagates in the semiconductor integrated circuit according to the present embodiment;

FIG. 11A is a layout diagram of a standard cell for supplying clocks, provided within a cell block in a semiconductor integrated circuit according to a second embodiment of the present invention;

FIG. 11B is a layout diagram of a standard cell for supplying clocks, provided within a cell block in the semiconductor integrated circuit according to the second embodiment;

FIG. 12 is a cross-sectional view of a standard cell (along a broken line A-B in FIG. 11A) in the semiconductor integrated circuit according to the second embodiment;

FIG. 13A is a layout diagram of a standard cell for supplying clocks, provided within a cell block in a semiconductor integrated circuit according to a third embodiment of the present invention;

FIG. 13B is a layout diagram of a standard cell for supplying clocks, provided within a cell block in the semiconductor integrated circuit according to the third embodiment;

FIG. 14A is a plan view of a cell block in the semiconductor integrated circuit according to the third embodiment;

FIG. 14B is a plan view of a cell block in the semiconductor integrated circuit according to the third embodiment;

FIG. 15A is a layout diagram of a cell block in the semiconductor integrated circuit according to the third embodiment (a layout diagram of a portion A of FIG. 14A);

FIG. 15B is a layout diagram of a cell block in the semiconductor integrated circuit according to the third embodiment (a layout diagram of a portion B of FIG. 14B); and

FIG. 16 is a layout diagram illustrating a different layout example of a cell block in the semiconductor integrated circuit according to the third embodiment (a layout diagram of the portion A of FIG. 14A).

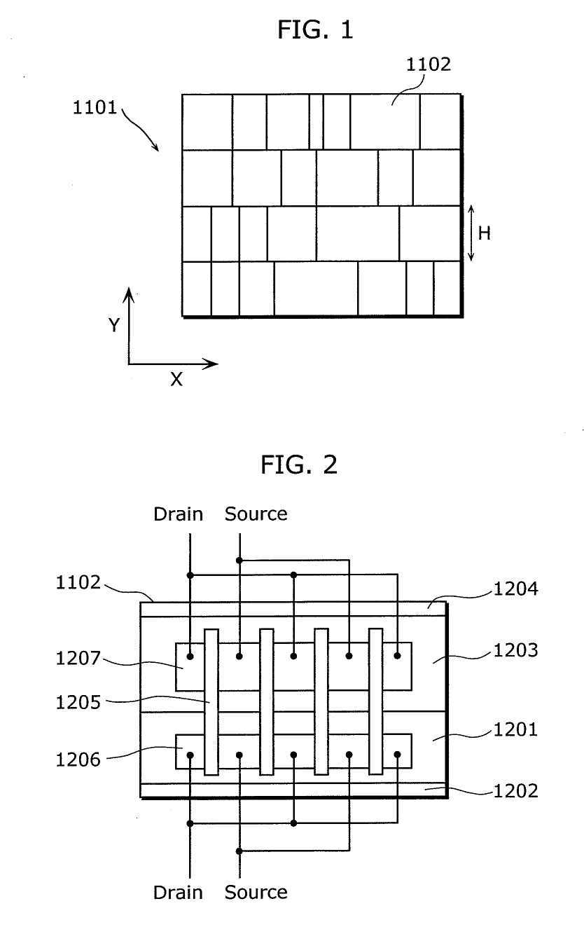

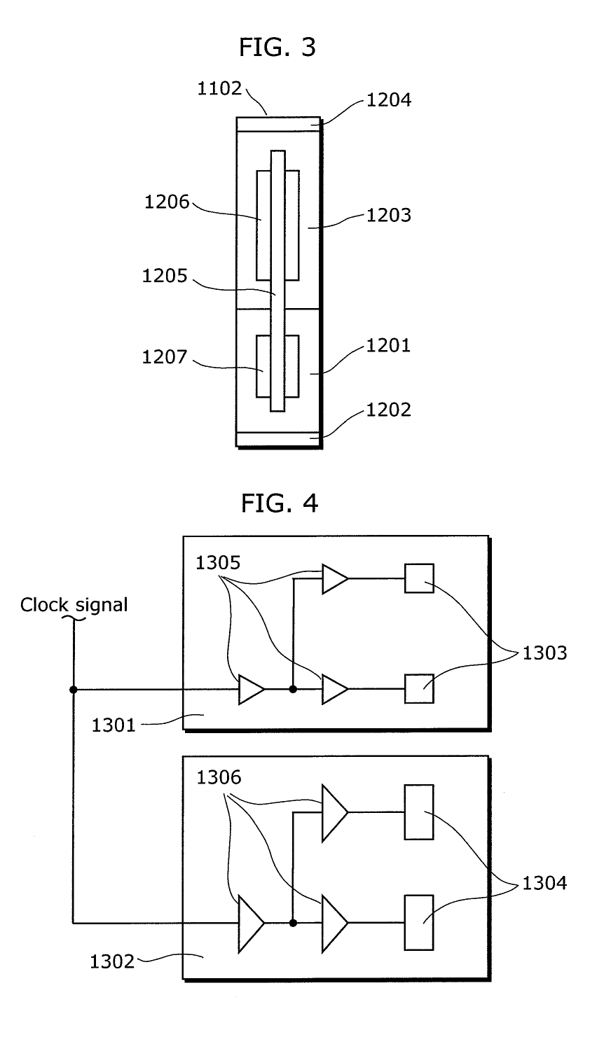

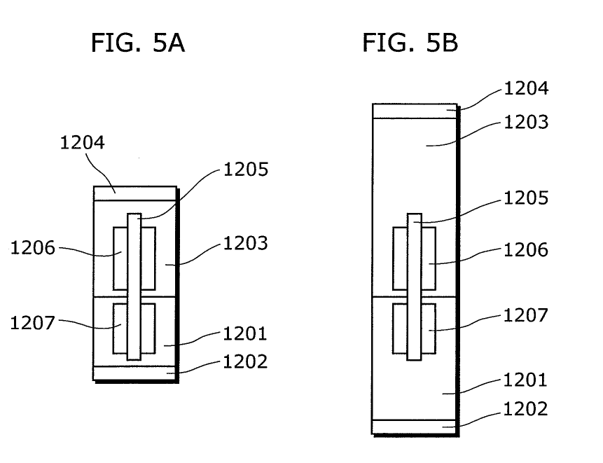

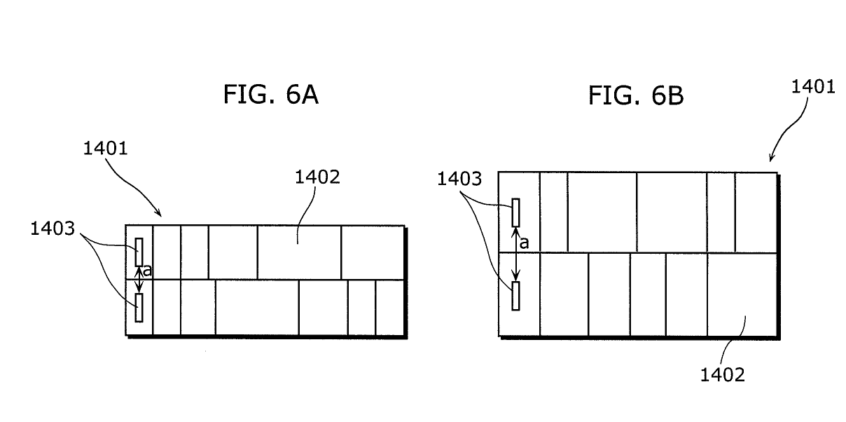

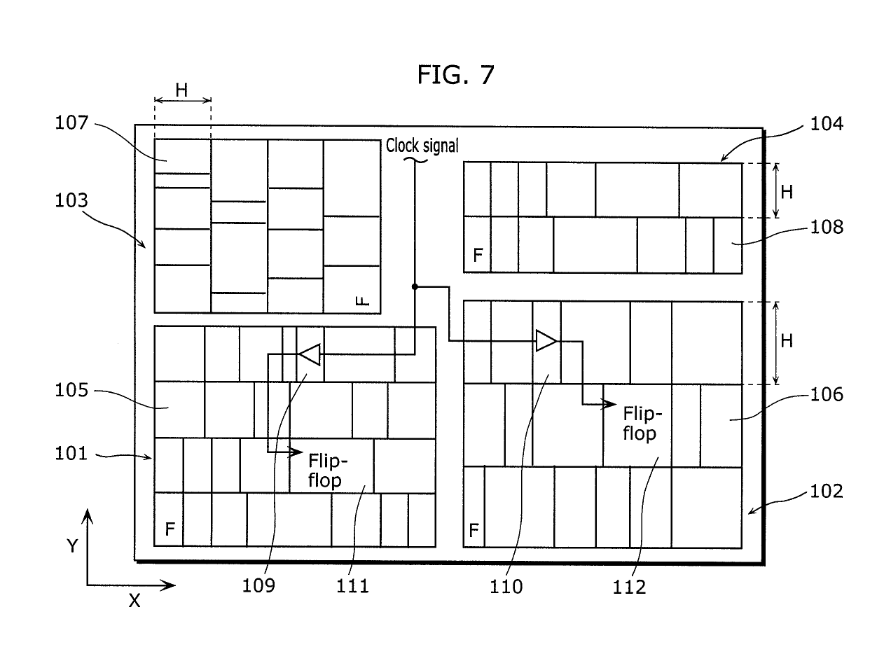

### DESCRIPTION OF THE PREFERRED EMBODIMENT(S)

Hereinafter, with reference to drawings, a detailed description of a semiconductor integrated circuit according to embodiments of the present invention shall be provided.

### First Embodiment

FIG. 7 is a plan view of a standard cell-type semiconductor integrated circuit according to a first embodiment of the present invention, illustrating an example of its layout.

FIG. 7 illustrates four cell blocks 101, 102, 103 and 104. The cell blocks 101 and 102 include columns in which plural standard cells 105 and 109, and plural standard cells 106 and 110 are arranged in the column direction, respectively. The cell blocks 103 and 104 include columns in which standard cells 107 and standard cells 108 are arranged in the column direction, respectively. In the cell block 101, the standard cells 105 and 109 having a short cell height are arranged. In the cell block 102, standard cells having a cell height taller than that of the standard cells 105 and 109 are arranged. In other words, the standard cells 106 and 110 having a tall cell height are arranged. In the cell blocks 103 and 104, the standard cells 107 and 108 having a short cell height, as short as that of the standard cells 105 in the cell block 101, are arranged, respectively.

Note that the column directions of all the cell blocks 101 to 104 in the semiconductor integrated circuit are not always the same. In the example illustrated in FIG. 7, the column direction of the cell blocks 101, 102 and 104 is the X-axis direction of FIG. 7, whereas the column direction of the cell block 103 is the Y-axis direction of FIG. 7. FIG. 7 indicates the column direction of each cell block with the orientation of the alphabetical letter “F” written in the corner of each of the cell blocks 101 to 104.

Further, as illustrated in FIG. 7, it is assumed that a clock signal in the semiconductor integrated circuit is supplied to a flip-flop 111 in the cell block 101 via the standard cell 109 in the cell block 101, and that the same clock signal is supplied to a flip-flop 112 in the cell block 102 via the standard cell 110 in the cell block 102. Here, the description is provided based on assumptions that the standard cells 109 and 110 are standard cells having an inverter logic circuit and are used for supplying clocks (clock cells) and that the standard cells 105 and 106 are standard cells other than the above mentioned standard cells.

Further, a transistor arranged in the standard cell 105 has a different size from the size of a transistor arranged in the standard cell 109, and a transistor arranged in the standard cell 106 has a different size from the size of a transistor arranged in the standard cell 110.

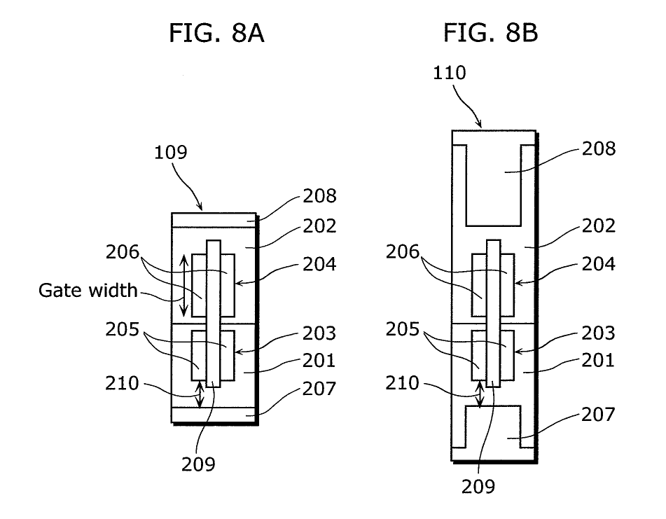

FIG. 8A is a layout diagram of the above described standard cell 109 for supplying clocks, provided within the cell block 101 illustrated in FIG. 7. FIG. 8B is a layout diagram of the above described standard cell 110 for supplying clocks, provided within the cell block 102 illustrated in FIG. 7. In FIGS. 8A and 8B, wires and contacts are omitted.

In each of the standard cells 109 and 110, a P-well region 201 and an N-well region 202 are arranged to be adjacent to each other. In the P-well region 201 in the standard cell 109, a pair of N-type diffusion regions 205 which serve as a source and a drain of an N-channel transistor 203 is arranged, and also, a P-type diffusion region 207 for supplying first substrate power to the standard cell 109 is arranged. In the P-well region 201 in the standard cell 110, a pair of N-type diffusion regions 205 which serve as a source and a drain of an N-channel transistor 203 is arranged, and also, a P-type diffusion region 207 for supplying second substrate power to the standard cell 110 is arranged. In the N-well region 202 in the standard cell 109, a pair of P-type diffusion regions 206 which serve as a source and a drain of a P-channel transistor 204 is arranged, and also, an N-type diffusion region 208 for supplying third substrate power to the standard cell 109 is arranged. In the N-well region 202 in the standard cell 110, a pair of P-type diffusion regions 206 which serve as a source and a drain of a P-channel transistor 204 is arranged, and also, an N-type diffusion region 208 for supplying fourth substrate power to the standard cell 110 is arranged.

Moreover, upon the P-well region 201 and the N-well region 202 of each of the standard cells 109 and 110, a gate electrode 209 which is made of polysilicon is arranged so as to continuously cover the mid-area between the above mentioned N-type diffusion regions 205 and the mid-area between the above mentioned P-type diffusion regions 206. The width of the gate electrode 209 is the same as the gate width of the transistor. FIG. 8A illustrates, as an example, the gate width of the P-channel transistor 204 of the standard cell 109. Note that the size of a transistor refers to the gate width.

Here, the shape of the N-channel transistor 203 in the standard cells 109 and the shape of the N-channel transistor 203 in the standard cells 110 are made substantially the same in conformity to the transistor in the standard cell 109 having the short cell height. To be more specific, the N-channel transistor 203 arranged in the standard cell 109 and the N-channel transistor 203 arranged in the standard cell 110 have substantially the same gate widths, and substantially the same areas of the N-type diffusion regions 205 which serve as source and drain diffusion regions.

In addition, with the N-channel transistor 203 arranged in the standard cell 109 and the N-channel transistor 203 arranged in the standard cell 110, a distance 210, in the standard cell 109, between the pair of N-type diffusion regions 205 which serve as source and drain diffusion regions and the P-type diffusion region 207 for substrate power supply is made substantially the same as a distance 210, in the standard cell 110, between the pair of N-type diffusion regions 205 which serve as source and drain diffusion regions and the P-type diffusion region 207 for substrate power supply, in conformity to the transistor in the standard cell 109 having the short cell height.

In a similar manner, the shape of the P-channel transistor 204 arranged in the standard cell 109 and the shape of the P-channel transistor 204 arranged in the standard cell 110 are made substantially the same in conformity to the transistor in the standard cell 109 having the short cell height. In addition, the distance, in the standard cell 109, between the pair of P-type diffusion regions 206 which serve as source and drain diffusion regions and the N-type diffusion region 208 for substrate power supply is made substantially the same as the distance, in the standard cell 110, between the pair of P-type diffusion regions 206 which serve as source and drain diffusion regions and the N-type diffusion region 208 for substrate power supply.

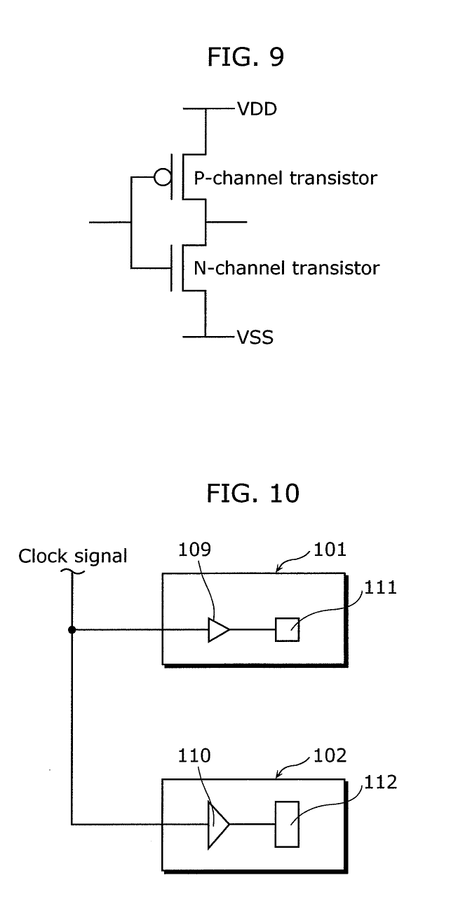

FIG. 9 is a diagram illustrating a transistor-level circuit of the standard cells 109 and 110 illustrated in FIG. 7.

The standard cells 109 and 110 are inverter cells, and the characteristics of the N-channel transistors have an impact on the length of time for propagating signals when an input signal rises, and an output signal falls. Also, when the input signal falls, and the output signal rises, the characteristics of the P-channel transistors have an impact on the length of time for propagating signals. In addition, between the standard cell 109 and the standard cell 110, by making the shapes of the transistors substantially the same, and making the distances between the source and drain diffusion regions of the transistors and the diffusion regions for substrate power supply substantially the same, it is possible to substantially match, between the standard cell 109 and the standard cell 110 having different cell heights, the characteristics of the transistors and the lengths of time for propagating signals.

FIG. 10 is a circuit configuration diagram illustrating a route that a clock signal propagates in the semiconductor integrated circuit illustrated in FIG. 7.

The clock signal is supplied to the flip-flop 111 in the cell block 101 via the standard cell 109 having the short cell height included in the cell block 101, and the same clock signal is supplied to the flip-flop 112 in the cell block 102 via the standard cell 110 having the tall cell height included in the cell block 102.

Here, between the standard cell 109 and the standard cell 110, the shapes of the transistors are made substantially the same, and the distances between the source and drain diffusion regions of the transistors and the diffusion regions for substrate power supply are made substantially the same. Therefore, it is possible to match the points of time that the clock signal reaches the flip-flop of the cell block 101 and the flip-flop of the cell block 102, which results in reduction in clock skew.

### Second Embodiment

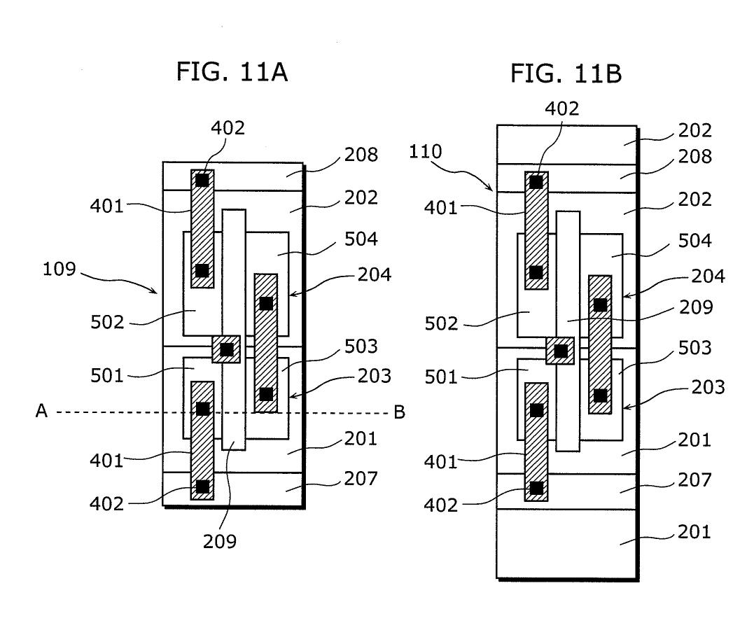

FIG. 11A and FIG. 11B are layout diagrams of a standard cell for supplying clocks, provided in the semiconductor integrated circuit according to a second embodiment of the present invention. FIG. 11A is a layout diagram of the standard cell 109 in the cell block 101 illustrated in FIG. 7, and FIG. 11B is a layout diagram of the standard cell 110 in the cell block 102 illustrated in FIG. 7. Note that the parts in FIGS. 11A and 11B that correspond to the parts in FIGS. 8A and 8B are denoted by the same numerical references, and the descriptions thereof are omitted. Here, as in FIGS. 8A and 8B. FIGS. 11A and 11B illustrate a case example where the standard cells 109 and 110 are inverter cells as illustrated in the circuit of FIG. 9.

FIGS. 11A and 11B illustrate metal wires 401 in a first metal wire layer. In FIGS. 11A and 11B, a source 501 of the N-channel transistor 203 is connected with the P-type diffusion region 207 for substrate power supply, via a contact 402 and a metal wire 401 in the first metal wire layer. In a similar manner, a source 502 of the P-channel transistor 204 is connected with the N-type diffusion region 208 for substrate power supply, via a contact 402 and a metal wire 401 in the first metal wire layer. In addition, a drain 503 of the N-channel transistor 203 is connected with a drain 504 of the P-channel transistor 204 via a contact 402 and a metal wire 401 in the first metal wire layer. The gate electrode 209 is connected with a metal wire 401 in the first metal wire layer via a contact 402 for connections with other standard cells.

Here, the shape of the N-channel transistor 203 in the standard cell 109 and the shape of the N-channel transistor 203 in the standard cell 110 are made substantially the same in conformity to the transistor in the standard cell 109 having the short cell height. To be more specific, between the N-channel transistor 203 arranged in the standard cell 109 and the N-channel transistor 203 arranged in the standard cell 110, the gate widths are made substantially the same, the areas of the sources 501 of the N-channel transistors 203 are made substantially the same, and the areas of the drains 503 of the N-channel transistors 203 are made substantially the same.

In addition, between the N-channel transistor 203 arranged in the standard cell 109 and the N-channel transistor 203 arranged in the standard cell 110, the distances between the N-type diffusion regions which serve as the sources 501 and the drains 503 and the P-type diffusion regions 207 for substrate power supply are made substantially the same in conformity to the transistor in the standard cell 109 having the short cell height.

In a similar manner, the shape of the P-channel transistor 204 arranged in the standard cell 109 and the shape of the P-channel transistor 204 arranged in the standard cell 110 are made substantially the same in conformity to the transistor in the standard cell 109 having the short cell height. In addition, the distances between the P-type diffusion regions which serve as the sources 502 and the drains 504 and the N-type diffusion regions 208 for substrate power supply are made substantially the same.

Furthermore, between the standard cell 109 and the standard cell 110, the shapes of the contacts 402 are made substantially the same, and the shapes of the metal wires 401 in the first metal wire layer connected with the transistors are made substantially the same. Also between the standard cell 109 and the standard cell 110, the distances between the gate electrodes 209 and the contacts 402 are made substantially the same, and the distances between the gate electrodes 209 and the metal wires 401 in the first metal wire layer are made substantially the same.

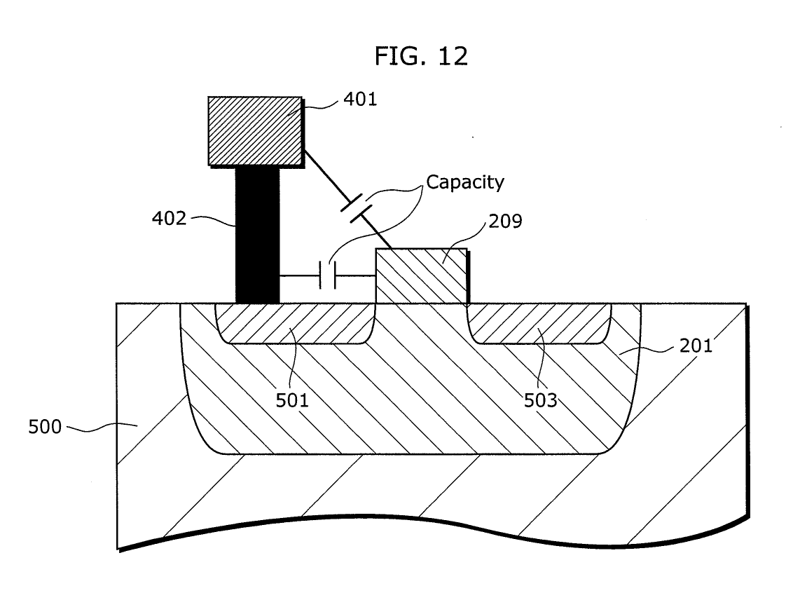

FIG. 12 is a cross-sectional view taken along a broken line A-B illustrated in FIG. 11A.

There is the P-well region 201 in a P-type substrate 500, and in the P-well region 201, there are the gate electrode 209 and the N-type diffusion regions which serve as the source 501 and the drain 503 of the N-channel transistor 203. The source 501 is connected with the metal wire 401 in the first metal wire layer via the contact 402.

As illustrated in FIG. 12, there is a capacity between the gate electrode 209 and the contact 402, and a capacity between the gate electrode 209 and the metal wire 401 in the first metal wire layer. Further, as illustrated in FIGS. 11A and 11B, the drain 503 and the gate electrode 209 of the transistor are also respectively connected with the metal wires 401 in the first metal wire layer via the contacts 402. Furthermore, although not illustrated in FIG. 12, there is also a capacity between these contacts 402, or between these metal wires 401 in the first metal wire layer. Moreover, there is also a capacity between these contacts 402 and these metal wires 401 in the first metal wire layer.

In FIG. 12, a capacitance value between the gate electrode 209 and the contact 402 is determined based on, for example, the distance between the gate electrode 209 and the contact 402, and on the areas of the surfaces of the gate electrode 209 and the contact 402 facing each other. In a similar manner, capacitance values of other capacities, such as the capacity between the contacts 402, the capacity between the metal wires 401 in the first metal wire layer, and the capacity between the contact 402 and the metal wire 401 in the first metal wire layer, are determined based on, for example, the distances and the areas of the cross sections. Further, in some cases, these capacities have an impact on the length of time that the P-channel transistors 204 and the N-channel transistors 203 take for propagating a signal. Consequently, even when different standard cells have the same shapes of the transistors, the lengths of time that the transistors take for propagating a signal do not match in some cases when the following are different between the standard cells: the shapes of the contacts; the shapes of the metal wires 401 in the first metal wire layer; the positional relationships between the gate electrodes and the contacts; and the positional relationships between the gate electrodes and the metal wires 401 in the first metal wire layer. This is because these differences cause differences in parasitic capacitances on the transistors.

With the semiconductor integrated circuit according to the present embodiment, by making the positions and shapes of the contacts 402 substantially the same between the standard cell 109 and 110, and making the positions and shapes of the metal wires 401 in the first metal wire layer substantially the same between the standard cell 109 and 110, it is possible to match, as much as possible, the capacities between the gate electrodes 209 and the contacts 402, between the gate electrodes 209 and the metal wires 401 in the first metal wire layer, between the contacts 402, between the metal wires 401 in the first metal wire layer, or between the contacts 402 and the metal wires, which results in reduction of a time lag, between the standard cells 109 and 110, for propagating a signal. As a result, by matching the lengths of delays between the standard cells, clock skew can be reduced.

### Third Embodiment

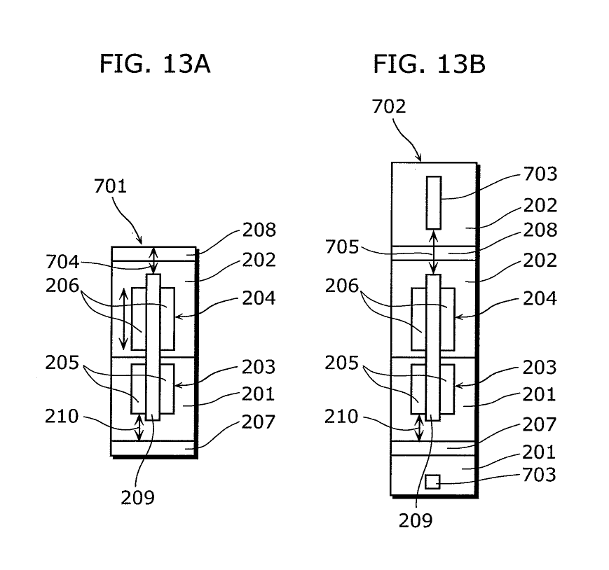

FIGS. 13A and 13B are layout diagrams of a standard cell for supplying clocks, provided in a semiconductor integrated circuit according to a third embodiment of the present invention. Note that the parts in FIGS. 13A and 13B that correspond to the parts in FIGS. 8A and 8B are denoted by the same numerical references, and the descriptions thereof are omitted. Here, as in FIGS. 8A and 8B, FIGS. 13A and 13B illustrate a case example where the standard cells are inverter cells as illustrated in the circuit of FIG. 9.

A standard cell 701 illustrated in FIG. 13A has a cell height shorter than that of a standard cell 702 illustrated in FIG. 13B. Further, in the standard cell 702 of FIG. 13B, a dummy gate wire 703 is arranged on the P-well region 201 and on the N-well region 202. Furthermore, a distance 705 in the standard cell 702 between the gate electrode 209 and the dummy gate wire 703 in the longitudinal direction of the gate is twice as long as a distance 704 in the standard cell 701 between the gate electrode 209 and a standard cell boundary (a boundary between the standard cell 701 and a standard cell adjacent to the standard cell 701) in the longitudinal direction of the gate.

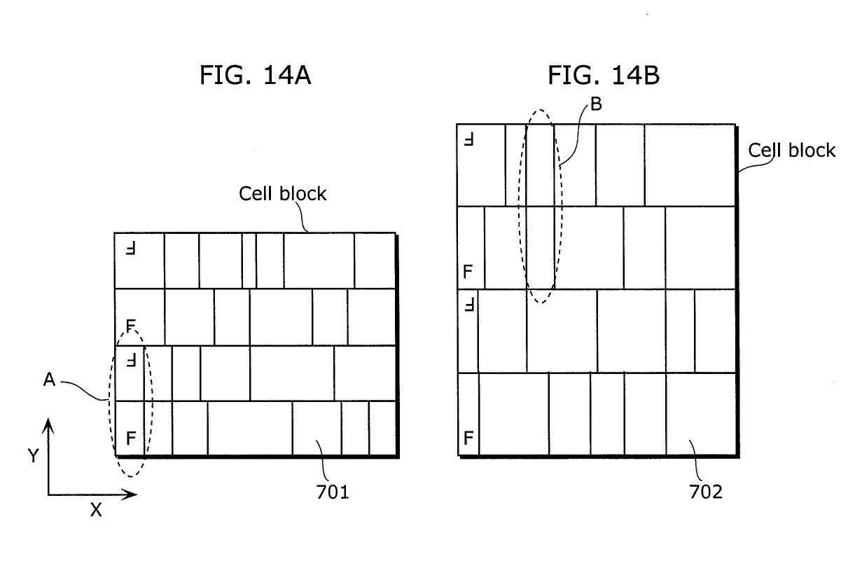

FIG. 14A is a plan view of a cell block in which the standard cells 701 are arranged. FIG. 14B is a plan view of a cell block in which the standard cells 702 are arranged. Note that the column direction of the standard cells 701 and 702 is the X-axis direction of FIGS. 14A and 14B. Also, the upward and downward directions of the standard cells are indicated by the orientation of the alphabetical letter “F”.

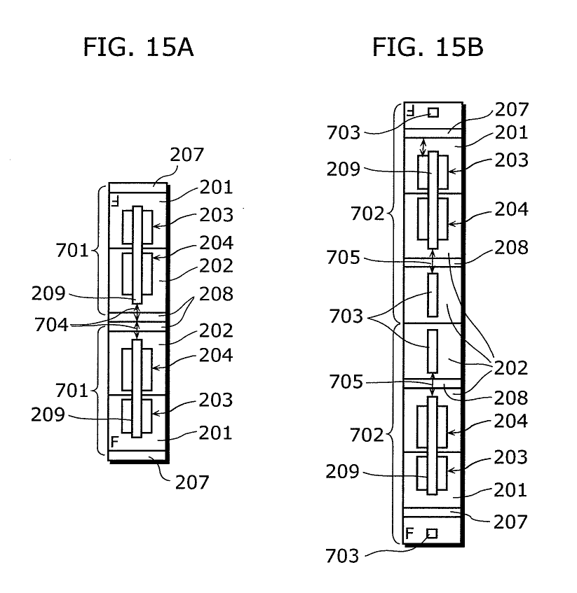

Further, FIG. 15A is a layout diagram of a part A surrounded by a broken line in FIG. 14A, and FIG. 15B is a layout diagram of a part B surrounded by a broken line in FIG. 14B. In FIGS. 15A and 15B, as in the FIGS. 14A and 14B, the upward and downward directions of the standard cells are indicated by the orientation of the alphabetical letter “F”.

As in the FIGS. 14A and 14B, the standard cells 701 and 702 are arranged in a way that they are turned upside down in every other column. This is because in the case where the standard cells are arranged in such a way that their upward and downward directions are the same in all columns, when, for example, there is a VDD power supply on the top edge of the standard cells (the N-type diffusion regions 208 of FIGS. 15A and 15B) and a VSS power supply on the bottom edge of the standard cells (the P-type diffusion regions 207 of FIGS. 15A and 15B), it is necessary to leave a space between columns in order to prevent a short between the VDD power supply and the VSS power supply. On the other hand, when the standard cells are turned upside down, there is no need to leave a space between columns since the VDD power supplies or the VSS power supplies face each other and it is unnecessary to take a precaution against shorts. For this reason, it is possible to eliminate a waste of areas by turning the standard cells 701 and 702 upside down in every other column.

As illustrated in FIG. 15A, the distance, in the longitudinal direction of the gate, between the gate electrodes 209 of the standard cells 701 arranged to be adjacent to each other in the vertical direction is twice as long as the distance 704 between the gate electrode 209 and the standard cell boundary. This distance is equal to the distance 705, as illustrated in FIG. 15B, between the gate electrode 209 of the standard cell 702 and the dummy gate wire 703. Therefore, by making the distance between the gate electrode 209 of the standard cell 701 and the gate electrode 209 of an adjacent standard cell and the distance between the gate electrode 209 of the standard cell 702 and the dummy gate wire 703 substantially the same, it is possible to reduce a time lag, between the standard cell 701 and the standard cell 702, in propagating signals. With the semiconductor integrated circuit according to the present embodiment, the description has been provided in regard to the P-channel transistors 204. Note, however, that even with the N-channel transistors 203, it is possible to obtain a similar effect in a similar manner by making the distance between a gate electrode of the standard cell 701 and another gate electrode of an adjacent standard cell and the distance between a gate electrode of the standard cell 702 and a dummy gate wire substantially the same.

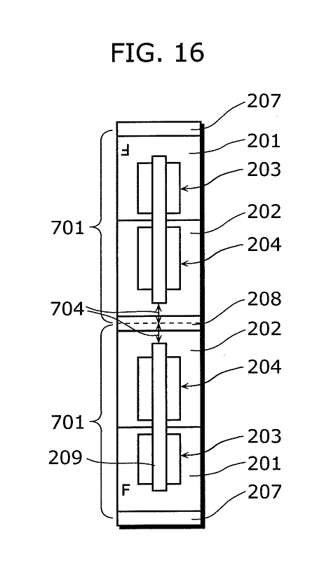

Further, FIG. 16 is a diagram illustrating a different example of a layout of the part A surrounded by the broken line in FIG. 14A.

In FIG. 16, the N-type diffusion regions 208 which are regions for VDD provided on the top edges of the standard cells 701 are arranged in such a way that they overlap each other. In the case of FIG. 16, the distance between the top edge of the gate electrode 209 and the midpoint of the N-type diffusion regions 208 for substrate power supply is considered as the distance 704 between the gate electrode 209 and the standard cell boundary.

Here, the semiconductor integrated circuit of the present embodiment has been illustrated with reference to the three diagrams (FIGS. 15A and 15B and FIG. 16). However, it is obvious that a similar effect can be obtained using a different layout of cell blocks in which standard cells are arranged, as long as the distance between a gate electrode and another gate electrode or a dummy gate wire in a cell block in the direction perpendicular to the column direction is the same as the distance between a gate electrode and another gate electrode or a dummy gate wire in another cell block in the direction perpendicular to the column direction.

The semiconductor integrated circuit according to the present invention has been described above based on some exemplary embodiments. Note, however, that the present invention is not limited to the above described embodiments. Various modifications which are obvious to those skilled in the art without departing from the scope of the present invention are intended to be included within the scope of the present invention.

For example, in the above embodiments, although it has been described that the clock cell (the standard cell for supplying clocks) is a cell having an inverter logic circuit, the present invention is not limited to the inverter logic circuit. It is obvious that a similar approach can also be applied to a cell having a logic circuit such as buffer, AND, OR, and MUX (selector).

Further, although a pair of N-type diffusion regions which serve as a source and a drain of a transistor has been described as an example of the first diffusion region and the third diffusion region of the present invention, the present invention is not limited to this, as long as they are diffusion regions included in a transistor.

Furthermore, although a pair of P-type diffusion regions which serve as a source and a drain of a transistor has been described as an example of the fifth diffusion region and the seventh diffusion region of the present invention, the present invention is not limited to this, as long as they are diffusion regions included in a transistor.

Moreover, although a P-type diffusion region for supplying first substrate power to a standard cell has been described as an example of the second diffusion region of the present invention, the present invention is not limited to this, as long as it is a diffusion region for supplying the first substrate power to a standard cell.

In addition, although a P-type diffusion region for supplying second substrate power to a standard cell has been described as an example of the fourth diffusion region of the present invention, the present invention is not limited to this, as long as it is a diffusion region for supplying the second substrate power to a standard cell.

Further, although an N-type diffusion region for supplying third substrate power to a standard cell has been described as an example of the sixth diffusion region of the present invention, the present invention is not limited to this, as long as it is a diffusion region is for supplying the third substrate power to a standard cell.

Furthermore, although an N-type diffusion region for supplying fourth substrate power to a standard cell has been described as an example of the eighth diffusion region of the present invention, the present invention is not limited to this, as long as it is a diffusion region for supplying the fourth substrate power to a standard cell.

Also, although P-well regions have been described as an example of the first well and the second well of the first conductivity type according to the present invention, the present invention is not limited to these, as long as they are well regions formed in a standard cell.

In addition, although N-well regions have been described as an example of the third well and the fourth well of the second conductivity type according to the present invention, the present invention is not limited to these, as long as they are well regions is formed in a standard cell.

### INDUSTRIAL APPLICABILITY

The present invention can be applied to semiconductor integrated circuits, and can particularly be applied to semiconductor integrated circuits and the like which enable reduction of clock skew in relation to clock signals.

1. A semiconductor integrated circuit comprising:
a first standard cell in which a first well of a first conductivity type is formed; and
a second standard cell in which a second well of the first conductivity type is formed, a cell height of said second standard cell being different from a cell height of said first standard cell,
wherein in said first well, the following are arranged:
a first diffusion region included in a first transistor; and
a second diffusion region for supplying first substrate power to said first standard cell,
in said second well, the following are arranged:
a third diffusion region included in a second transistor; and
a fourth diffusion region for supplying second substrate power to said second standard cell, and
a distance between said first diffusion region and said second diffusion region is substantially the same as a distance between said third diffusion region and said fourth diffusion region.

2. The semiconductor integrated circuit according to claim 1,
wherein the first transistor and the second transistor have the same shapes, gate widths, and areas of source and drain diffusion regions.

3. The semiconductor integrated circuit according to claim 2,
wherein a third well of a second conductivity type is formed in said first standard cell,
a fourth well of a second conductivity type is formed in said second standard cell,
in said third well, the following are arranged:
a fifth diffusion region included in a third transistor; and
a sixth diffusion region for supplying third substrate power to said first standard cell,
in said fourth well, the following are arranged:
a seventh diffusion region included in a fourth transistor; and
an eighth diffusion region for supplying fourth substrate power to said second standard cell, and
a distance between said fifth diffusion region and said sixth diffusion region is substantially the same as a distance between said seventh diffusion region and said eighth diffusion region.

4. The semiconductor integrated circuit according to claim 3,
wherein said first standard cell includes a first metal wire in a first metal wire layer, said first metal wire being connected with the first transistor,
said second standard cell includes a second metal wire in the first metal wire layer, said second metal wire being connected with the second transistor, and
said first metal wire and said second metal wire have substantially the same shapes.

5. The semiconductor integrated circuit according to claim 4,
wherein the cell height of said second standard cell is taller than the cell height of said first standard cell,
said first standard cell includes a gate electrode included in the first transistor,
said second standard cell includes a dummy gate wire and a gate electrode included in the second transistor, and
a distance between said gate electrode of said second standard cell and said dummy gate wire is twice as long as a distance between said gate electrode of said first standard cell and a boundary between said first standard cell and a cell adjacent to said first standard cell.

6. The semiconductor integrated circuit according to claim 5,
wherein said first and second standard cells are cells having an inverter logic circuit.

7. The semiconductor integrated circuit according to claim 5,
wherein said first and second standard cells are cells having a buffer logic circuit.

8. The semiconductor integrated circuit according to claim 5,
wherein said first and second standard cells are cells having an AND logic circuit.

9. The semiconductor integrated circuit according to claim 1,
wherein a third well of a second conductivity type is formed in said first standard cell,
a fourth well of a second conductivity type is formed in said second standard cell,
in said third well, the following are arranged:
a fifth diffusion region included in a third transistor; and
a sixth diffusion region for supplying third substrate power to said first standard cell,
in said fourth well, the following are arranged:
a seventh diffusion region included in a fourth transistor; and
an eighth diffusion region for supplying fourth substrate power to said second standard cell, and
a distance between said fifth diffusion region and said sixth diffusion region is substantially the same as a distance between said seventh diffusion region and said eighth diffusion region.

10. The semiconductor integrated circuit according to claim 1,
wherein said first standard cell includes a first metal wire in a first metal wire layer, said first metal wire being connected with the first transistor,
said second standard cell includes a second metal wire in the first metal wire layer, said second metal wire being connected with the second transistor, and
said first metal wire and said second metal wire have substantially the same shapes.

11. The semiconductor integrated circuit according to claim 1,
wherein the cell height of said second standard cell is taller than the cell height of said first standard cell,
said first standard cell includes a gate electrode included in the first transistor,
said second standard cell includes a dummy gate wire and a gate electrode included in the second transistor, and
a distance between said gate electrode of said second standard cell and said dummy gate wire is twice as long as a distance between said gate electrode of said first standard cell and a boundary between said first standard cell and a cell adjacent to said first standard cell.

12. The semiconductor integrated circuit according to claim 1,
wherein said first and second standard cells are cells having an inverter logic circuit.

13. The semiconductor integrated circuit according to claim 1,
wherein said first and second standard cells are cells having a buffer logic circuit.

14. The semiconductor integrated circuit according to claim 1,
wherein said first and second standard cells are cells having an AND logic circuit.
